(19) United States
(12) Patent Application Publication
(10) Pub. No.: US 2025/0365899 A1
(43) Pub. Date: Nov. 27, 2025

(54) CONNECTOR

(71) Applicant: YAZAKI CORPORATION, Tokyo (JP)

(72) Inventors: Yasuhiro Yamaguchi, Kakegawa-shi (JP); Shinsuke Aoshima, Fujieda-shi (JP)

(21) Appl. No.: 19/211,115

(22) Filed: May 16, 2025

(30) Foreign Application Priority Data
May 22, 2024 (JP) 2024-083437

(51) Int. Cl. H05K 7/20; H01R 4/34; H01R 4/56; H01R 13/506; H01R 13/52

(52) U.S. Cl. CPC H05K 7/20409; H01R 4/34; H01R 4/56; H05K 7/2049; H01R 13/506; H01R 13/5202; H01R 13/5205; H01R 2201/26

(57) ABSTRACT

A connector includes: a connection terminal that is electrically connected to a mating terminal; a wiring-member terminal that is provided at an end of a conductive wiring member, and electrically connected to the connection terminal; a heat storage member that is mounted to the wiring-member terminal; a terminal fastening part where the connection terminal and the wiring-member terminal are fastened via a first fastening member; and a heat storage member fastening part where the wiring-member terminal and the heat storage member are fastened via a second fastening member. The terminal fastening part and the heat storage member fastening part are provided at different positions from each other on the wiring-member terminal.

### CROSS-REFERENCE TO RELATED APPLICATION(S)

The present application claims priority to and incorporates by reference the entire contents of Japanese Patent Application No. 2024-083437 filed in Japan on May 22, 2024.

### BACKGROUND OF THE INVENTION

### 1. Field of the Invention

The present invention relates to a connector.

### 2. Description of the Related Art

For example, Japanese Patent Application Laid-open No. 2012-221 612 A discloses a connector that includes a plurality of terminals and a housing having a terminal housing part that houses and holds the terminals.

By the way, the connector described in Japanese Patent Application Laid-open No. 2012-221 612 A is expected to be able to handle high currents in order to respond to larger battery capacity and shorter charging time. In such a case, when a high current flows between connectors, the amount of heat generated from high resistance points increases and the heat accumulates in the heat generation source, which may cause the temperature inside the connectors to increase rapidly.

### SUMMARY OF THE INVENTION

The present invention is designed in view of the aforementioned circumstances, and it is therefore an object thereof to provide a connector capable of properly absorbing heat from a heat generation source and suppressing a rapid increase in the temperature.

In order to achieve the above mentioned object, a connector according to one aspect of the present invention includes a connection terminal that is electrically connected to a mating terminal; a wiring-member terminal that is provided at an end of a wiring member exhibiting conductivity, and electrically connected to the connection terminal; a heat storage member that is mounted to the wiring-member terminal; a terminal fastening part where the connection terminal and the wiring-member terminal are fastened via a first fastening member; and a heat storage member fastening part where the wiring-member terminal and the heat storage member are fastened via a second fastening member, wherein the terminal fastening part and the heat storage member fastening part are provided at different positions from each other on the wiring-member terminal.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view illustrating a schematic configuration of a connector according to an embodiment;

FIG. 2 is an exploded perspective view illustrating a schematic configuration of the connector according to the present embodiment;

FIG. 3 is a sectional view taken along the height direction of the connector according to the present embodiment;

FIG. 4 is an enlarged sectional view of FIG. 3;

FIG. 5 is a perspective view illustrating a schematic configuration of a heat storage member applied to the connector according to the present embodiment;

FIG. 6 is a perspective view illustrating a schematic configuration of the heat storage member applied to the connector according to the present embodiment;

FIG. 7 is a perspective view illustrating a schematic configuration of a cover member applied to the connector according to the present embodiment; and

FIG. 8 is a sectional view taken along the width direction of the connector according to the present embodiment.

### DETAILED DESCRIPTION OF THE PREFERRED EMBODIMENTS

Hereinafter, an embodiment according to the present invention will be described in detail with reference to the accompanying drawings. Note, however, that the present invention is not limited by the embodiment. Furthermore, structural components in the following embodiment include those that can be easily replaced by those skilled in the art, or those that are substantially the same.

### Embodiment

A connector 1 according to an embodiment is applied to a wire harness used in a vehicle such as an automobile, for example, and used in a connection mechanism for connecting a wire to an electrical device to electrically connect a wiring member W to a mating device.

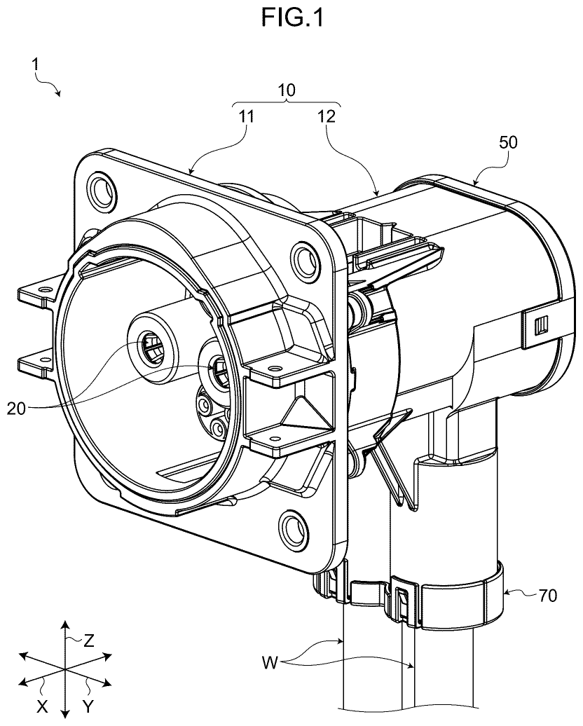

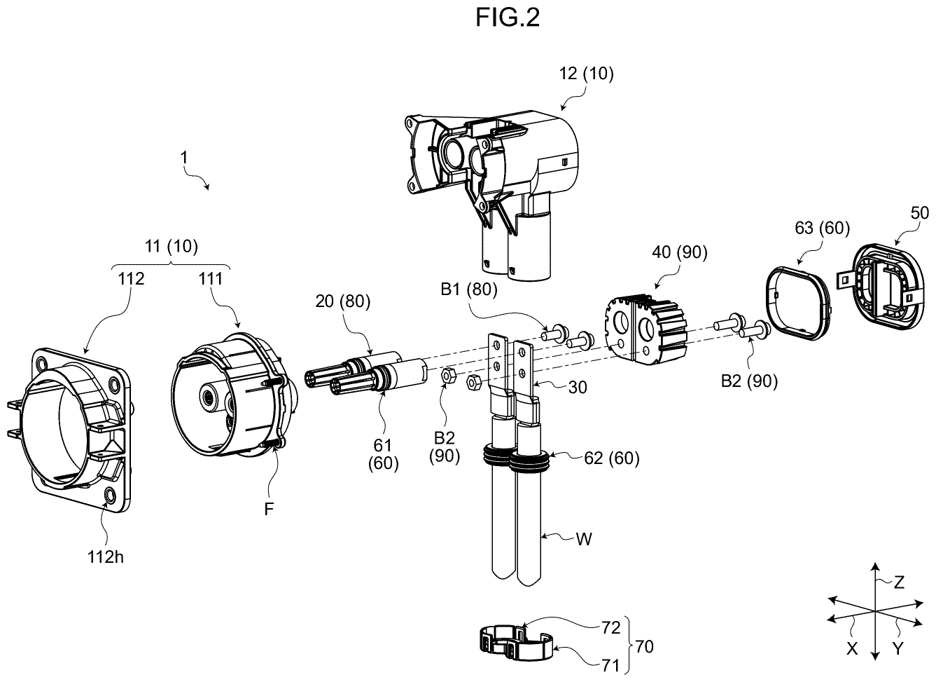

As illustrated in FIG. 1 and FIG. 2, a wire harness includes the wiring members W exhibiting conductivity and the connector 1.

The wiring member W is routed in a vehicle to electrically connect each device. The wiring member W according to the present embodiment is an insulated wire configured including a conductor part (core wire) exhibiting conductivity and an insulation sheath part exhibiting insulation property, in which the conductor part is covered by the insulation sheath part. The conductor part herein is a stranded wire formed with a plurality of strands made of a conductive metal twisted together. The insulation sheath part is formed by extrusion molding of an insulating resin material (PP, PVC, cross-linked PE, or the like, which is selected as appropriate considering abrasion resistance, chemical resistance, heat resistance, and the like).

The connector 1 includes connection terminals 20 that are electrically connected to mating terminals, wiring-member terminals 30 that are provided at ends of the wiring members W and electrically connected to the connection terminals 20, and heat storage members 40 that are mounted to the wiring-member terminals 30 (see FIG. 2). In the connector 1 according to the present embodiment, a terminal fastening part 80 where the connection terminal 20 and the wiring-member terminal 30 are fastened via a first fastening member B1 and a heat storage member fastening part 90 where the wiring-member terminal 30 and the heat storage member 40 are fastened via a second fastening member B2 are provided separately, thereby achieving a configuration capable of properly absorbing the heat from a heat generation source and suppress a rapid increase in the temperature. Hereinafter, each configuration of the connector 1 will be described in detail with reference to FIG. 1 to FIG. 8.

In addition, the wire harness may further include a protector, a grommet, a fixture, and the like.

In the description hereinafter, in regards to a first direction, a second direction, and a third direction intersecting with each other, the first direction is referred to as an “axial direction X”, the second direction as a “width direction Y”, and the third direction as a “height direction Z”. Herein, the axial direction X, the width direction Y, and the height direction Z are orthogonal to each other. The axial direction X typically corresponds to the axial direction (extending direction) of the connection terminal 20, the fitting direction of the connection terminal 20 with respect to the mating terminal, and the like. The width direction Y typically corresponds to the width direction and the like of a housing 10 that houses the connection terminals 20, the wiring-member terminals 30, and the heat storage members 40. The height direction Z typically corresponds to the height direction and the like of the housing 10. Furthermore, unless otherwise noted, each of the directions used in the following description will be described as the direction in a state where members configuring the connector 1 are mounted to each other.

Furthermore, the top end side in the axial direction X typically corresponds to the mating connector or the like in a state where the connector 1 is being fitted to the mating connector on the power supply side, and the base end side in the axial direction X typically corresponds to the connector 1 side or the like in a state where the connector 1 is being fitted to the mating connector.

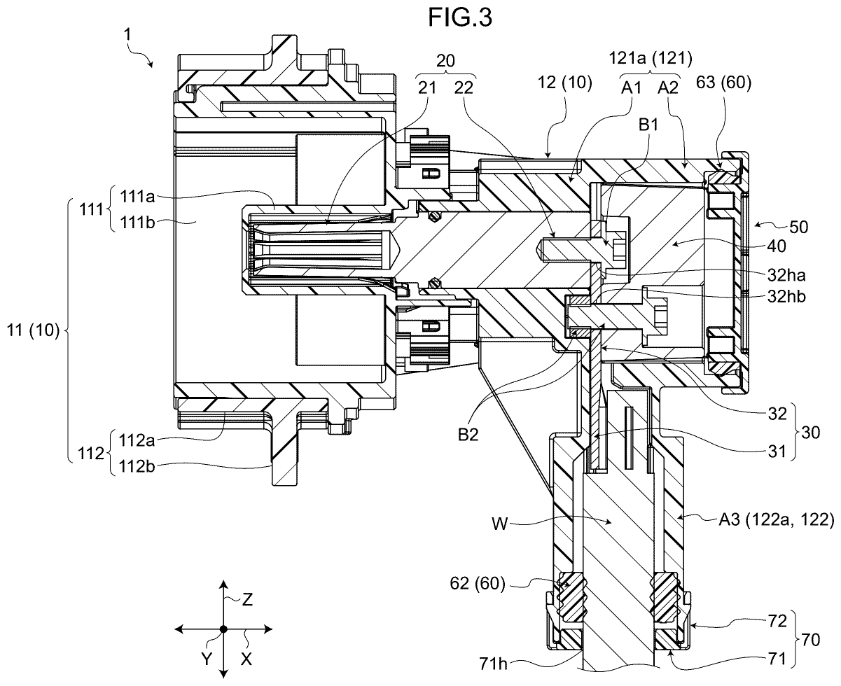

As illustrated in FIG. 2 and FIG. 3, the connector 1 is configured including the housing 10, the connection terminals 20, the wiring-member terminals 30, the heat storage members 40, a cover member 50, water sealing members 60, a rear holder 70, the terminal fastening part 80, and the heat storage member fastening part 90.

### Housing

The housing 10 is formed with a synthetic resin material exhibiting insulation property, and houses and holds inside thereof the connection terminals 20, the wiring-member terminals 30 provided at the ends of the wiring members W, and the heat storage members 40. As illustrated in FIG. 1 to FIG. 3, the housing 10 is configured including a first housing 11 and a second housing 12.

The first housing 11 houses and holds electrical connection parts 21 of the connection terminals 20 described later. As illustrated in FIG. 2, the first housing 11 is configured including an inner housing 111 and an outer housing 112 that houses inside thereof the inner housing 111.

As illustrated in FIG. 3, the inner housing 111 includes a terminal housing part 111a and a hood part 111b. The terminal housing part 111a is a part that is formed as a substantially circular cylinder shape along the axial direction X, and houses and holds inside thereof the connection terminal 20. The hood part 111b is a part that is formed as a substantially circular cylinder shape along the axial direction X, and houses inside thereof the terminal housing part 111a. In the inner housing 111 according to the present embodiment, a pair of terminal housing parts 111a are provided spaced apart along the width direction Y, and the electrical connection part 21 of the connection terminal 20 is housed in each of the terminal housing parts 111a.

As illustrated in FIG. 3, the outer housing 112 includes an outer housing main body part 112a and a flange part 112b. The outer housing main body part 112a is a part that is formed as a substantially circular cylinder shape along the axial direction X, and houses and holds inside thereof the inner housing 111. The flange part 112b is a part that is formed protruding from the outer face side of the outer housing main body part 112a, and it is fixed to an installation target part when the connector 1 is installed in the installation target part such as a vehicle body. The flange part 112b according to the present embodiment is formed in a plate-like shape along a plane orthogonal to the axial direction X (a plane extending along the width direction Y and the height direction Z) (see FIG. 2). In addition, the flange part 112b is provided with collar members 112h that are integrally molded by a molding method such as insert molding. Thus, the first housing 11 according to the present embodiment is fixed to the installation target part by inserting screws F (see FIG. 2) into the collar members 112h provided in the flange part 112b of the outer housing 112. Furthermore, when the connector 1 is fitted to a mating connector, the first housing 11 can hold the mating connector in a detachable manner by housing the housing and the like of the mating connector on the inner side of the hood part 111b of the inner housing 111.

The second housing 12 houses and holds fastening parts 22 of the connection terminals 20 described later, the wiring-member terminals 30 provided at the ends of the wiring members W, and the heat storage members 40. As illustrated in FIG. 3, the second housing 12 is configured including a first main body part 121 and a second main body part 122.

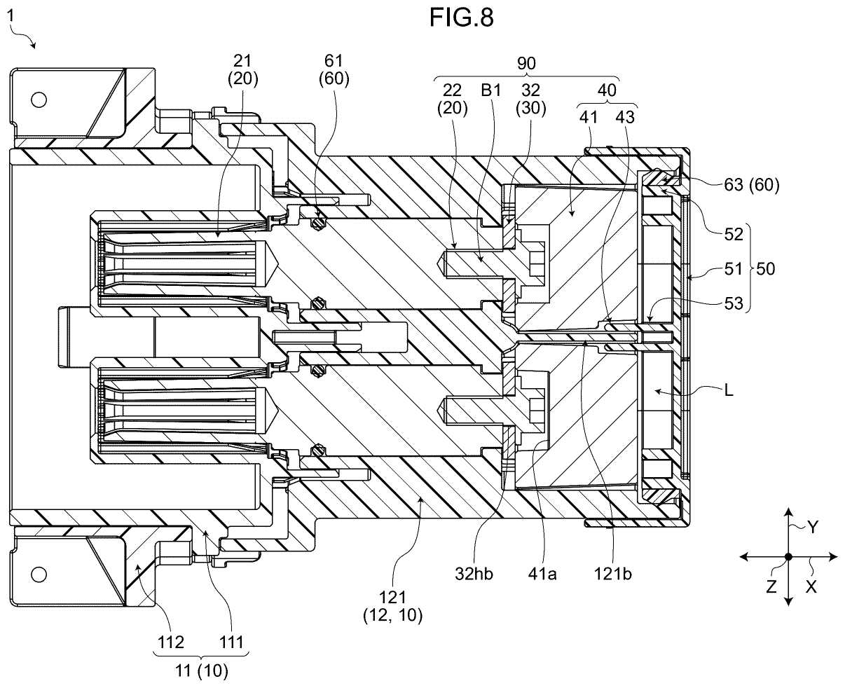

As illustrated in FIG. 3, the first main body part 121 includes a housing part 121a. Furthermore, the housing part 121a includes a first area A1 communicating with the terminal housing part 111a, and a second area A2 communicating with the first area A1. The first area A1 is a part that is formed as a substantially circular cylinder shape along the axial direction X, and houses and holds inside thereof the fastening part 22 of the connection terminal 20. Furthermore, the second area A2 is a part that is formed as a substantially semi-elliptical cylinder shape along the axial direction X, and houses and holds inside thereof a member connection part 32 of the wiring-member terminal 30 placed neighboring to the connection terminal 20 along the axial direction X as well as the heat storage member 40 placed neighboring to the wiring-member terminal 30. In the first main body part 121 according to the present embodiment, a pair of housing parts 121a are provided spaced apart along the width direction Y, and the fastening part 22 of the connection terminal 20, the member connection part 32 of the wiring-member terminal 30, and the heat storage member 40 are housed in each of the housing parts 121a. When two second areas A2 of the first main body part 121 are combined, the cross-sectional shape thereof comes to be in a substantially elliptical shape (an elliptical shape with the major axis being the width direction Y and the minor axis being the height direction Z). Furthermore, between the second areas A2 of the first main body part 121, a partition wall 121b formed in a plate-like shape along a plane orthogonal to the width direction Y (a plane extending along the axial direction X and the height direction Z) is provided (see FIG. 8). Therefore, the first main body part 121 according to the present embodiment can prevent the wiring-member terminals 30 housed in the second areas A2 from contacting each other and, at the same time, can prevent the heat storage members 40 from contacting each other.

As illustrated in FIG. 3, the second main body part 122 includes a housing part 122a. The housing part 122a is a part that includes a third area A3 communicating with the second area A2 of the first main body part 121, and it is formed in a substantially circular cylinder shape along the height direction Z to house and hold inside thereof a wiring-member connection part 31 of the wiring-member terminal 30 and the end of the wiring member W to which the wiring-member terminal 30 is connected (that is, end of the wire-with-terminal). In the second main body part 122 according to the present embodiment, a pair of housing parts 122a are provided spaced apart along the width direction Y, and the end of the wire-with-terminal is housed in each of the housing parts 122a.

### Connection Terminal

The connection terminal 20 is a power terminal that is formed with a conductive metal material and electrically connected to a mating terminal when the connector 1 and a mating connector are fitted. As illustrated in FIG. 3, the connection terminal 20 is configured including the electrical connection part 21 and the fastening part 22.

As illustrated in FIG. 3, the electrical connection part 21 is a part that is provided on the top end side in the axial direction X, and connects to the mating terminal when the connector 1 is fitted to the mating connector.

The electrical connection part 21 according to the present embodiment is configured with a plurality of elastic contact pieces arranged in an annular shape, and it is capable of electrically connecting to the mating terminal by having the mating terminal inserted inside thereof.

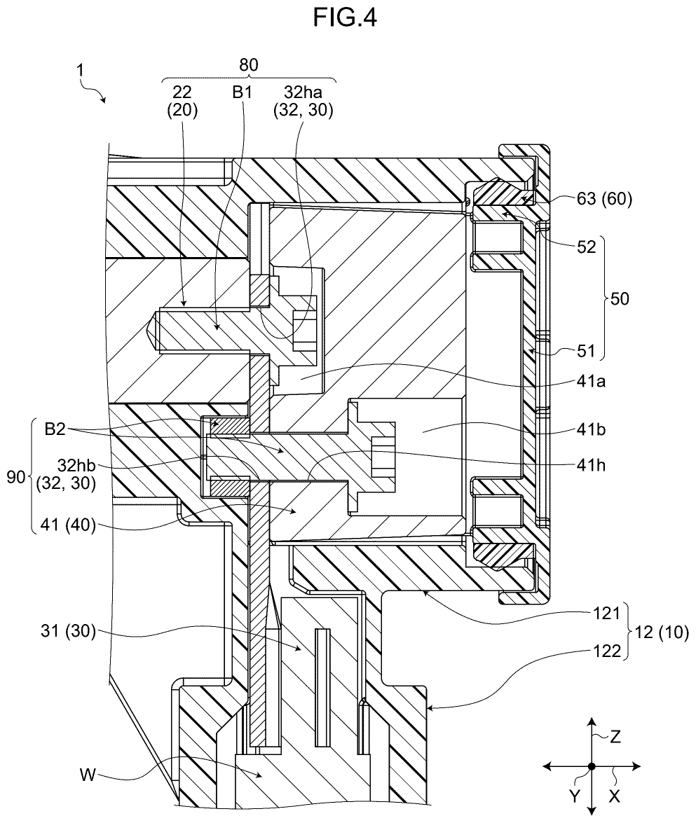

As illustrated in FIG. 3 and FIG. 4, the fastening part 22 is a female threaded part provided on the base end side in the axial direction X. The fastening part 22 according to the present embodiment is provided at the bottom of the base part of the connection terminal 20 (the part connecting each of the elastic contact pieces configuring the electrical connection part 21), and configures the terminal fastening part 80 (see FIG. 4) described later by being screwed onto the male threaded part of the first fastening member B1.

Note that the shape of the connection terminal 20 is not limited to the shape illustrated in FIG. 2 (so-called slotted terminal), but can be changed as appropriate to suit the specifications of the mating connector and the specifications of the connector 1.

### Wiring-Member Terminal

The wiring-member terminal 30 is a flat terminal that is formed with a conductive metal material, and provided at the end of the wiring member W by being caulked against the conductor part of the wiring member W. As illustrated in FIG. 3 and FIG. 4, the wiring-member terminal 30 is configured including the wiring-member connection part 31 and the member connection part 32.

As illustrated in FIG. 3 and FIG. 4, the wiring-member connection part 31 is a part that is provided on the base end side (lower side in the height direction Z) and crimped to the conductor part (core-wire exposed part) exposed by peeling off the insulation sheath part of the wiring member W, and it is a part to be the main heat generation source in the connector 1. The wiring-member connection part 31 according to the present embodiment is configured with a pair of barrel pieces, for example, and it is crimped to the wiring member W by caulking the core-wire exposed part of the wiring member W with the pair of barrel pieces.

As illustrated in FIG. 3 and FIG. 4, the member connection part 32 is provided on the top end side (upper side in the height direction Z), and it is a part in which two hole parts 32ha and 32hb opened through along the axial direction X are provided. The member connection part 32 according to the present embodiment configures the terminal fastening part 80 (see FIG. 4) described later by having the male threaded part of the first fastening member B1 inserted into the hole part 32ha and the male threaded part screwed onto the female threaded part of the fastening part 22 of the connection terminal 20. Furthermore, the member connection part 32 configures the heat storage member fastening part 90 (see FIG. 4) described later by having the male threaded part of the second fastening member B2 inserted into the hole part 32hb and the male threaded part screwed onto the female threaded part of the second fastening member B2.

### Heat Storage Member

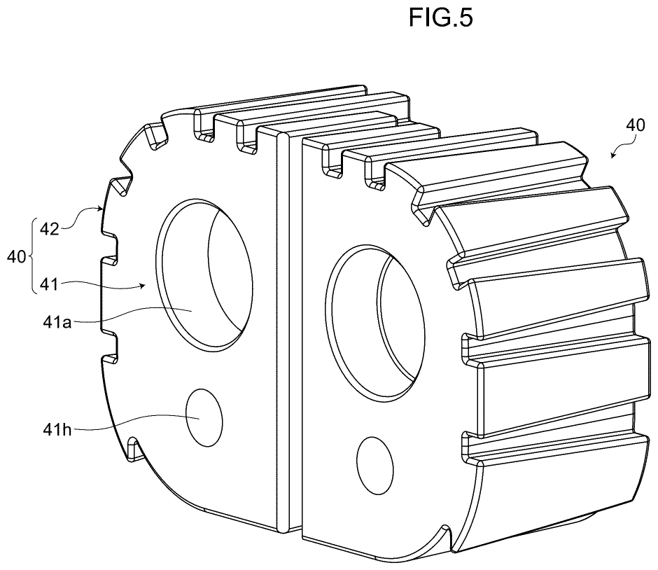

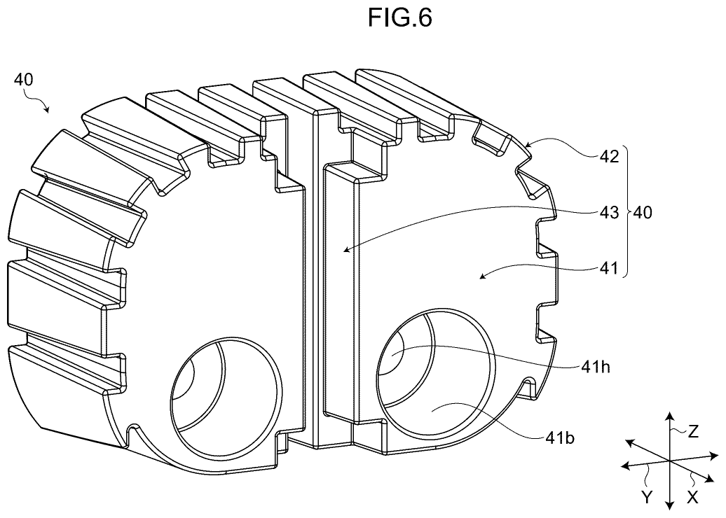

The heat storage member 40 is formed with a conductive metal member, and absorbs and stores the heat generated from the heat generation source. As illustrated in FIG. 5 and FIG. 6, the heat storage member 40 is configured including a heat storage member main body part 41, heat dissipation fins 42, and a notch part 43.

The heat storage member main body part 41 is a part that absorbs and stores the heat from the connection terminal 20 and the wiring-member terminal 30. As illustrated in FIG. 5 and FIG. 6, the heat storage member main body part 41 according to the present embodiment is formed as a substantially semi-elliptical column shape along the axial direction X and, when two of which are combined, the cross-sectional shape thereof forms a substantially elliptical shape (an elliptical shape with the major axis being the width direction Y and the minor axis being the height direction Z). Furthermore, as illustrated in FIG. 4 to FIG. 6, the heat storage member main body part 41 includes a first recessed part 41a, a second recessed part 41b, and a hole part 41h communicating with the second recessed part 41b. As illustrated in FIG. 4 and FIG. 5, the first recessed part 41a is a recessed part for avoiding the screw head of the first fastening member B1 of the terminal fastening part 80 described later. The first recessed part 41a according to the present embodiment is provided in the front face of the heat storage member 40 (the face that is placed facing the wiring-member terminal 30). Furthermore, the first recessed part 41a is formed from the front face of the heat storage member 40 toward the cover member 50 side described later, and it is formed in a shape recessed along the axial direction X. As illustrated in FIG. 4 and FIG. 6, the second recessed part 41b is a recessed part (so called counterbore) for avoiding the screw head of the second fastening member B2 of the heat storage member fastening part 90 described later. The second recessed part 41b according to the present embodiment is provided on the back face of the heat storage member 40 (the face that is on the opposite side of the front face of the heat storage member 40, and it is placed facing the cover member 50 described later). Furthermore, the second recessed part 41b is formed from the back face of the heat storage member 40 toward the wiring-member terminal 30 side, and it is formed in a shape recessed along the axial direction X. As illustrated in FIG. 4 and FIG. 5, the hole part 41h is a through hole for inserting the male threaded part of the first fastening member B1 into the terminal fastening part 80 described later. The hole part 41h according to the present embodiment is formed along the axial direction X from the bottom part of the second recessed part 41b provided on the back face of the heat storage member 40 toward the wiring-member terminal 30 side.

As illustrated in FIG. 5 and FIG. 6, the heat dissipation fin 42 is a protrusion piece that is formed protruding from the outer face side of the heat storage member main body part 41, and it is formed in a straight shape along the axial direction X. As for the heat dissipation fin 42 according to the present embodiment, there are a plurality of those provided along the circumferential direction of the heat storage member main body part 41. The width of the protrusion pieces configuring the heat dissipation fins 42 is formed to become narrower from the front face side of the heat storage member 40 to the back face side of the heat storage member 40. On the contrary, the width between the protrusion pieces is formed to become wider from the front face side of the heat storage member 40 toward the back face side of the heat storage member 40. Therefore, the heat storage member 40 can suppress a rapid increase in the temperature inside the connector 1 by dissipating the heat accumulated in the heat storage member main body part 41 through the heat dissipation fins 42.

The notch part 43 is a recessed part for avoiding a rib 53 of the cover member 50 described later. The notch part 43 of the present embodiment is provided on the back face of the heat storage member 40, as illustrated in FIG. 6. Furthermore, the notch part 43 is formed from the back face of the heat storage member 40 toward the wiring-member terminal 30 side (see FIG. 8), and it is formed in a shape recessed along the axial direction X. As illustrated in FIG. 6, the notch part 43 is formed in a straight shape along the height direction Z by being provided in the straight part of the heat storage member main body part 41 that is formed in a substantially semi-elliptical column shape. Therefore, the notch part 43 has the axial direction X as the depth direction and the height direction Z as the extending direction. The notch parts 43 formed in each of a pair of heat storage members 40 are placed neighboring to each other.

Note that it is preferable for the heat storage member 40 to be formed with a material with a large thermal capacity or a material with a higher thermal conductivity than other members. By accumulating more heat in the heat storage member main body part 41 and more efficiently dissipating the heat via the heat dissipation fins 42, a rapid increase in the temperature inside the connector 1 can be more securely suppressed.

### Cover Member

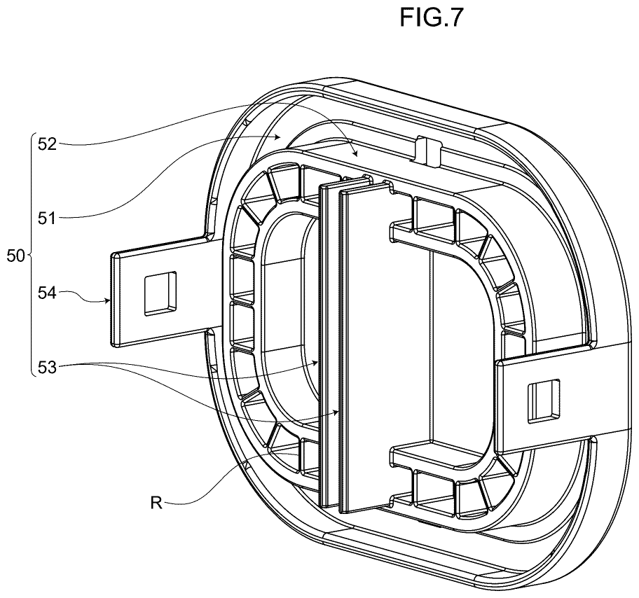

The cover member 50 is formed with a synthetic resin material exhibiting insulation property, and closes the opening part of the second housing 12 (the opening part that allows the second area A2 of the first main body part 121 to communicate with the outside). As illustrated in FIG. 7 and FIG. 8, the cover member 50 is configured including a cover main body part 51, a packing attachment part 52, ribs 53, and locked parts 54.

As illustrated in FIG. 8, the cover main body part 51 is a part that covers the opening part of the second housing 12 by being mounted to the end part of the first main body part 121 of the second housing 12 (the end part located on the base end side in the axial direction X). As illustrated in FIG. 7, the cover main body part 51 according to the present embodiment is formed in a plate-like shape along a plane orthogonal to the axial direction X (a plane extending along the width direction Y and the height direction Z), and it is formed in a shape to fit the first main body part 121 of the second housing 12 (an elliptic shape with the axis being the width direction Y and the minor axis being the height direction Z). Therefore, the cover main body part 51 can cover the back face of the heat storage member 40 by being placed to face the heat storage members 40 housed inside the second housing 12, as illustrated in FIG. 8.

The packing attachment part 52 is an annular wall part formed protruding from the cover main body part 51, and it is a part to which a cover packing 63 described later is attached. As illustrated in FIG. 7 and FIG. 8, the packing attachment part 52 according to the present embodiment is formed protruding in the axial direction X. Furthermore, the packing attachment part 52 is placed at a position overlapping with the heat storage members 40 when viewed from the axial direction X, and placed between the heat storage members 40 and the cover main body part 51.

Therefore, in the connector 1 according to the present embodiment, an air layer L is formed between the heat storage members 40 and the cover member 50. Thus, with the connector 1, it is possible to suppress a rapid increase in the temperature inside the connector 1 by releasing the heat accumulated in the heat storage members 40 to the air layer L through the heat dissipation fins 42.

The rib 53 is a plate-like wall part formed protruding from the cover main body part 51, and it is a part placed between the heat storage members 40 provided as a pair. In the present embodiment, a pair of ribs 53 are provided and formed in a plate-like shape along a plane orthogonal to the width direction Y (a plane extending along the axial direction X and the height direction Z), as illustrated in FIG. 7 and FIG. 8. The pair of ribs 53 are formed protruding in the axial direction X from the cover main body part 51 side toward the heat storage member 40 side, and placed in a state of being fitted into the notch part 43 provided in the peripheral edge part of the heat storage member, as illustrated in FIG. 8. Moreover, the pair of ribs 53 are placed in respective clearance parts that are formed by the notch parts 43 formed in the heat storage members 40 and the partition walls 121b formed in the second housing 12, as illustrated in FIG. 8. Thus, the pair of ribs 53 are placed by overlapping with the heat storage members 40 on one side and overlapping with the partition walls 121b formed in the second housing 12 on the other side. Therefore, the connector 1 according to the present embodiment can ensure the insulation distance between the heat storage members 40 (anode and cathode) while ensuring a sufficient volume of the heat storage members 40, thereby making it possible to more appropriately prevent the heat storage members 40 from being electrically connected to each other.

In addition, a reinforcement part R is provided between the annular wall part configuring the packing attachment part 52 and the annular wall part provided on the inner side of the wall part. As illustrated in FIG. 7, the reinforcement part R according to the present embodiment is configured with a plurality of ribs extending toward the wall part configuring the packing attachment part 52, thereby making it possible to reinforce the wall part configuring the packing attachment part 52 so as not to collapse. Therefore, it is possible with the connector 1 according to the present embodiment to suppress distortion of the shape of the packing attachment part 52, so that the cover member 50 can be properly attached to the housing 10.

As illustrated in FIG. 7, the locked part 54 is a locked frame part formed protruding from the cover main body part 51, and it is a part that fixes the cover member 50 to the second housing 12 by being locked to a claw-shaped locking protrusion part formed on the first main body part 121 of the second housing 12. In the present embodiment, a pair of locked parts 54 are provided spaced apart along the width direction Y.

### Water Sealing Member

The water sealing member 60 is formed by elastic synthetic rubber, and prevents liquids such as water from entering the interior of the connector 1. As illustrated in FIG. 2 and FIG. 3, the water sealing member 60 is configured including terminal packings 61, rubber stoppers 62, and a cover packing 63.

As illustrated in FIG. 2, the terminal packing 61 is formed in an annular shape and attached between the electrical connection part 21 and the fastening part 22 of the connection terminal 20. As illustrated in FIG. 3, the terminal packing 61 according to the present embodiment is placed in a compressed state between the outer peripheral face of the connection terminal 20 inserted via the through hole of the terminal packing 61 and the inner peripheral face of the housing part 121a of the second housing 12, when the connection terminal 20 is mounted to the second housing 12. Therefore, the terminal packing 61 can prevent liquids such as water from entering the terminal housing part 111a of the first housing 11 communicating with the housing part 121a of the second housing 12.

The rubber stopper 62 is formed in an annular shape and attached to the wiring member W, as illustrated in FIG. 2. As illustrated in FIG. 3, the rubber stopper 62 according to the present embodiment is placed in a compressed state between the outer peripheral face of the wiring member W inserted via the through hole of the rubber stopper 62 and the inner peripheral face of the housing part 122a of the second housing 12, when the end of the wiring member W is mounted to the second housing 12. Therefore, the rubber stopper 62 can prevent liquids such as water from entering the interior of the second housing 12.

As illustrated in FIG. 2, the cover packing 63 is formed in an annular shape and attached to the cover member 50 described later. As illustrated in FIG. 3, the cover packing 63 according to the present embodiment is placed in a compressed state between the outer peripheral face of the packing attachment part 52 of the cover member 50 inserted via the through hole of the cover packing 63 and the inner peripheral face of the housing part 121a of the second housing 12, when the cover member 50 is mounted to the second housing 12. Therefore, the cover packing 63 can prevent liquids such as water from entering the interior of the second housing 12.

### Rear Holder

The rear holder 70 is formed with a synthetic resin material exhibiting insulation property, and holds the rubber stopper 62 that is attached to the wiring member W. As illustrated in FIG. 2 and FIG. 3, the rear holder 70 is configured including a rear holder main body part 71 and a locked part 72.

As illustrated in FIG. 3, the rear holder main body part 71 is a part that has a hole part 71h opened through along the height direction Z, and holds the wiring member W by being mounted to the end part of the second main body part 122 of the second housing 12 (an end part located on the lower side in the height direction Z) in a state where the wiring member W is being inserted into the hole part 71h. In the rear holder main body part 71 according to the present embodiment, a pair of hole parts 71h are provided spaced apart along the width direction Y, and the wiring member W is inserted into each of the hole parts 71h. Thus, the rear holder 70 is capable of holding two wiring members W.

The locked part 72 is a locked frame part formed protruding from the rear holder main body part 71, and it is a part that fixes the rear holder 70 to the second housing 12 by being locked to a claw-shaped locking protrusion part formed on the second main body part 122 of the second housing 12 (see FIG. 2 and FIG. 3). In the present embodiment, two locked parts 72 are provided to one rear holder main body part 71, so that there are a total of four provided therein.

### Terminal Fastening Part

The terminal fastening part 80 is a part where the connection terminal 20 and the wiring-member terminal 30 are fastened via the first fastening member B1. As illustrated in FIG. 4, the terminal fastening part 80 is configured with the fastening part 22 of the connection terminal 20, the top end side (upper side in the height direction Z) of the member connection part 32 of the wiring-member terminal 30, and the first fastening member B1.

Note that the first fastening member B1 herein is a bolt. Therefore, by inserting the male thread part of the bolt along the axial direction X into the hole part 32ha formed on the top end side of the member connection part 32 of the wiring-member terminal 30 and by screwing the male thread part of the bolt onto the female thread part of the fastening part 22 of the connection terminal 20, the terminal fastening part 80 is fastened while having the wiring-member terminal 30 sandwiched between the screw head of the bolt and the connection terminal 20.

Furthermore, the heat storage member 40 described above is not fastened to the connection terminal 20 and the wiring-member terminal 30 in the terminal fastening part 80. Therefore, the terminal fastening part 80 according to the present embodiment can fasten only two members that are the connection terminal 20 and the wiring-member terminal 30 placed side by side along the axial direction X by the first fastening member B1.

### Heat Storage Member Fastening Part

The heat storage member fastening part 90 is a part where the wiring-member terminal 30 and the heat storage member 40 are fastened via the second fastening member B2. As illustrated in FIG. 4, the heat storage member fastening part 90 is configured with the base end side (lower side in the height direction Z) of the member connection part 32 of the wiring-member terminal 30, the heat storage member 40, and the second fastening member B2.

Note that the second fastening member B2 herein is a bolt and a nut. Therefore, by inserting the male thread part of the bolt along the axial direction X into the hole part 32hb formed on the based end side of the member connection part 32 of the wiring-member terminal 30 and by screwing the male thread part of the bolt onto the female thread part of the nut, the heat storage member fastening part 90 is fastened while having the wiring-member terminal 30 and the heat storage member 40 sandwiched between the screw head of the bolt and the nut.

Furthermore, the connection terminal 20 described above is not fastened to the wiring-member terminal 30 and the heat storage member 40 in the heat storage member fastening part 90. Therefore, the heat storage member fastening part 90 according to the present embodiment can fasten only the wiring-member terminal 30 and the heat storage member 40 that are placed side by side along the axial direction X by the second fastening member B2.

Furthermore, the terminal fastening part 80 and the heat storage member fastening part 90 described above are provided at different positions from each other on the wiring-member terminal 30, as illustrated in FIG. 4. The heat storage member fastening part 90 is provided between the wiring-member connection part 31 of the wiring-member terminal 30 and the terminal fastening part 80, and it is provided at a position closer to the wiring-member connection part 31 of the wiring-member terminal 30 than the terminal fastening part 80 is. Therefore, the heat storage member fastening part 90 according to the present embodiment enables the heat storage member 40 to efficiently absorb the heat generated in the wiring-member connection part 31 of the wiring-member terminal 30 as the heat generation source, so that it is possible to prevent the heat from concentrating in the heat storage member fastening part 90.

Furthermore, by fastening the members formed with metal materials to each other by the second fastening member B2, the heat storage member fastening part 90 can ensure, by the axial force of the bolt, the surface pressure generated when the wiring-member terminal 30 and the heat storage member 40 come in contact. Thus, the heat storage member fastening part 90 according to the present embodiment can connect the wiring-member terminal 30 and the heat storage member 40 with low interfacial thermal resistance (that is, the wiring-member terminal 30 and the heat storage member 40 are connected in a state where both members are being brought in close contact), so that the thermal conductivity between the wiring-member terminal 30 and the heat storage member 40 is increased. This enables the heat storage member 40 to efficiently absorb the heat generated in the wiring-member terminal 30.

The connector 1 described above includes: the connection terminal 20 that is electrically connected to a mating terminal; the wiring-member terminal 30 that is provided at the end of the wiring member W exhibiting conductivity, and electrically connected to the connection terminal 20; the heat storage member 40 that is mounted to the wiring-member terminal 30; the terminal fastening part 80 where the connection terminal 20 and the wiring-member terminal 30 are fastened via the first fastening member B1; and the heat storage member fastening part 90 where the wiring-member terminal 30 and the heat storage member 40 are fastened via the second fastening member B2, in which the terminal fastening part 80 and the heat storage member fastening part 90 are provided at different positions from each other on the wiring-member terminal 30.

With such a configuration, the heat storage member fastening part 90 allows the heat storage member 40 to absorb the heat generated on the wiring-member terminal 30 side by mounting the heat storage member 40 to the wiring-member terminal 30 using the second fastening member B2. In addition, by separately providing the terminal fastening part 80 and the heat storage member fastening part 90, it is possible to prevent the heat generated in the wiring-member terminal 30 from concentrating at one point. Therefore, the connector 1 according to the present embodiment can properly absorb the heat from the heat generation source and suppress a rapid increase in the temperature. Furthermore, since the connector 1 can suppress a rapid increase in the temperature, a cooling structure is not required. Thus, it is possible to satisfy the temperature requirement without increasing the diameter of the wiring member. Therefore, with the connector 1, it is possible to suppress increase in the size of the body while satisfying the temperature requirement.

Furthermore, the heat storage member fastening part 90 described above is provided between the terminal fastening part 80 and the wiring-member connection part 31 where the conductor part of the wiring member W and the wiring-member terminal 30 are electrically connected. With such a configuration, the heat storage member fastening part 90 can improve the heat absorption efficiency of the heat storage member 40 by shortening the distance with respect to the wiring-member connection part 31 as the heat generation source such that the heat generated in the wiring-member connection part 31 is not transmitted to the terminal fastening part 80 side. This makes it possible to prevent the heat from concentrating between the connection terminal 20 and the wiring-member terminal 30. Therefore, the connector 1 according to the present embodiment can properly absorb the heat from the heat generation source and suppress a rapid increase in the temperature. In addition, the connector 1 has the heat storage member fastening part 90 provided on the inner side than the terminal fastening part 80 is, so that it is not necessary to increase the size of the housing 10. Thus, it is possible to suppress increase in the size of the body.

Furthermore, the heat storage member 40 described above is not fastened to the connection terminal 20 and the wiring-member terminal 30 in the terminal fastening part 80, and the connection terminal 20 is not fastened to the wiring-member terminal 30 and the heat storage member 40 in the heat storage member fastening part 90. With such a configuration, the terminal fastening part 80 can prevent the axial force of the first fastening member B1 from decreasing due to creep deformation or the like of the heat storage member 40, since the heat storage member 40 is not fastened to the connection terminal 20. This makes it possible to prevent the connection terminal 20 from becoming loosened. Furthermore, since the connection terminal 20, the wiring-member terminal 30, and the heat storage member 40 are not fastened together, the terminal fastening part 80 and the heat storage member fastening part 90 can suppress increase in the ambient temperature (temperature in the periphery of the fastening parts). Therefore, the connector 1 according to the present embodiment can suppress creep deformation of the heat storage member 40 in the heat storage member fastening part 90.

In addition, the heat storage member 40 described above has a plurality of heat dissipation fins 42 formed protruding from the outer face side. With such a configuration, the heat storage member 40 can efficiently release the heat inside the connector 1 to the outside by dissipating the heat absorbed and accumulated from the wiring-member terminal 30 through the heat dissipation fins 42. Therefore, the connector 1 according to the present embodiment can properly absorb the heat from the heat generation source and suppress a rapid increase in the temperature still more.

Note that the connector 1 according to the embodiment of the present invention described above is not limited to the embodiment described above, and various changes are possible within the scope of the appended claims.

For example, the positional relationship between the wiring-member connection part 31, the terminal fastening part 80, and the heat storage member fastening part 90 is not specifically limited. In the description above, the heat storage member fastening part 90 is described to be provided between the wiring-member connection part 31 and the terminal fastening part 80 (that is, the wiring-member connection part 31, the heat storage member fastening part 90, and the terminal fastening part 80 are placed side by side in this order). However, the positions of the terminal fastening part 80 and the heat storage member fastening part 90 may be reversed.

In addition, the distance between the wiring-member connection part 31 and the heat storage member fastening part 90 is not specifically limited. Furthermore, the distance between the heat storage member fastening part 90 and the terminal fastening part 80 is not specifically limited.

Moreover, while the heat storage member 40 is described to be formed with a metal member, the constituent material of the heat storage member 40 is not specifically limited as long as it is a material that can absorb and store the heat generated from the heat generation source, and may be formed with a material other than a metallic material (for example, a resin material).

Furthermore, the heat storage member 40 may not have the heat dissipation fins 42.

In addition the shape of the heat storage member main body part 41 of the heat storage member 40 and the shape of the heat dissipation fins 42 are not specifically limited.

Furthermore, the connector 1 according to the present embodiment may be configured by combining the structural components of the embodiment described above as appropriate.

The connector according to the present embodiment has such an effect that it can properly absorb the heat from the heat generation source and suppress a rapid increase in the temperature.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A connector comprising:
a connection terminal that is electrically connected to a mating terminal;
a wiring-member terminal that is provided at an end of a wiring member exhibiting conductivity, and electrically connected to the connection terminal;
a heat storage member that is mounted to the wiring-member terminal;
a terminal fastening part where the connection terminal and the wiring-member terminal are fastened via a first fastening member; and
a heat storage member fastening part where the wiring-member terminal and the heat storage member are fastened via a second fastening member, wherein
the terminal fastening part and the heat storage member fastening part are provided at different positions from each other on the wiring-member terminal.

2. The connector according to claim 1, wherein
the heat storage member fastening part is provided between the terminal fastening part and a wiring-member connection part where a conductor part of the wiring member and the wiring-member terminal are electrically connected.

3. The connector according to claim 1, wherein
the heat storage member is not fastened to the connection terminal and the wiring-member terminal in the terminal fastening part, and
the connection terminal is not fastened to the wiring-member terminal and the heat storage member in the heat storage member fastening part.

4. The connector according to claim 2, wherein
the heat storage member is not fastened to the connection terminal and the wiring-member terminal in the terminal fastening part, and
the connection terminal is not fastened to the wiring-member terminal and the heat storage member in the heat storage member fastening part.

5. The connector according to claim 1, wherein
the heat storage member includes a plurality of heat dissipation fins formed protruding from an outer face side.

6. The connector according to claim 2, wherein
the heat storage member includes a plurality of heat dissipation fins formed protruding from an outer face side.
